(19) United States
(12) Patent Application Publication
(10) Pub. No.: US 2008/0025095 A1
(43) Pub. Date: Jan. 31, 2008

(54) FLASH MEMORY DEVICE AND PROGRAM METHOD THEREOF

(76) Inventors: Se-Jin Ahn, Seoul (KR); Tae-Keun Jeon, Seoul (KR)

Correspondence Address: F. CHAU & ASSOCIATES, LLC, 130 WOODBURY ROAD, WOODBURY, NY, 11797, US

(21) Appl. No.: 11/776,109

(22) Filed: Jul. 11, 2007

(30) Foreign Application Priority Data
Jul. 26, 2006 (KR) 2006-70386

(51) Int. Cl. G11C 16/04; G11C 16/06

(52) U.S. Cl. 365/185.11; 365/185.18

(57) ABSTRACT

A flash memory device and method of programming a flash memory device which include an array of memory cells arranged in rows and columns. A method includes programming memory cells of a selected row with loaded data; determining whether the memory cells of the selected row are successfully programmed; when the judgment result is determined as a unsuccessful program operation, determining a reprogram operation according to flag information indicating an on/off state of the reprogram operation stored in the flash memory device; and when the flag information indicates an on state of the reprogram information, reprogramming the loaded data to memory cells of a different row from the selected row.

### CROSS-REFERENCE TO RELATED APPLICATIONS

This U.S. non-provisional patent application claims priority under 35 U.S.C § 119 of Korean Patent Application 2006-70386 filed on Jul. 26, 2006, the disclosure of which is hereby incorporated by reference.

### BACKGROUND OF THE INVENTION

1. Technical Field

The present disclosure relates to a semiconductor memory device and, more particularly, to a flash memory device.

2. Discussion of the Related Art

There is increasing need for semiconductor memory devices that can be programmed and erased electronically without refreshing the data stored therein. The trend in the industry is to increase the storage volume and the degree of integration of semiconductor memory devices. A flash memory device is an exemplary non-volatile semiconductor memory device which provides large volume and high integration degree without refresh of stored data. Because it can retain data without power, the flash memory device is widely used in electronic devices, such as portable computers, PMP, MP3 players, mobile phones, and the like, which are more prone to power interruptions.

FIG. 1 is a block diagram showing a conventional memory system including a flash memory device. A conventional memory system includes a flash memory device 100 and a memory controller 200. The flash memory device 100 may perform read, program and erase operations under the control of the memory controller 200. For example, when a program operation is requested from an external source (e.g., host), data (e.g., a page amount of data) to be programmed may be transferred to a buffer memory 201 of the memory controller 200 from the external source. Once data is transferred to the buffer memory 201, the memory controller 200 may transfer the command, address, and data to the flash memory device 100 according to a given timing, which is discussed in the section immediately following with reference to FIG. 2.

In a first interval P1, the memory controller 200 may transfer a command and an address to the flash memory device 100. In a second interval P2, the memory controller 200 may transfer data (e.g., page data) stored in the buffer memory 201 to the flash memory device 100 that had previously been called during a data load time. When the page data stored in the buffer memory 201 is fully transferred to the flash memory device 100 in a third interval P3, the flash memory device 100 may carry out a program operation according to a standard industry manner. If a program operation is completed in a fourth interval P4, the memory controller 200 may confirm a program result from the flash memory device 100.

In the event that the program result indicates an unsuccessful program operation the memory controller 200 may resend the command, address and data to the flash memory device 100 for a reprogram operation in which case, the resent address may be a page address of another memory location. This is because memory cells of the flash memory device 100 are not overwritten as is standard practice in this art. In other words, memory cells may be erased and programmed in order to store new data to programmed memory cells. For this reason, program-failed data may be programmed in another memory location, or block via a block replacement function as is conventional practice in the art. Accordingly, in a case where an unsuccessful program operation occurs, reprogramming of the data may lower the overall operation speed of a memory system (or, a flash memory device).

To improve a program speed, page data to be programmed next may be sent to the buffer memory 201 from an external host during execution of a program operation. According to this data transfer scheme, an additional buffer memory 201 for storing data sent to the flash memory device 100 may be included within the memory controller 200 in order to support a reprogram operation to be carried out at unsuccessful program operation. This often increases the cost of the memory controller 200.

As a result, there is a need for a technique which automatically performs a reprogram operation without external control, without data reloading when unsuccessful programming occurs, and without lowering of the operation speed when unsuccessful programming occurs.

### SUMMARY OF THE INVENTION

An exemplary embodiment of the present invention is a method of programming a flash memory device which includes an array of memory cells arranged in rows and columns, comprised of programming memory cells of a selected row with loaded data and determining whether the memory cells of the selected row are successfully programmed. When the determined result is an unsuccessful program operation, selecting a reprogram operation according to flag information indicating an on/off state of the reprogram operation stored in the flash memory device. When the flag information indicates an on state of the reprogram information reprogramming the loaded data to memory cells of a different row from the selected row. The logic states of the reprogram information are reversible without modification of the embodiment provided the interpretation is consistent.

The different row memory cells may further be selected by address information stored in the flash memory device.

Address information and the flag information may further be stored in a backup parameter storage component of the flash memory device.

Address information and the flag information may further be loaded onto a backup parameter storage component from the array at power-up.

Address information and the flag information may further be loaded onto a backup parameter storage component from the external source before a normal operation.

Address information and the flag information may further be loaded onto a backup parameter storage component from the external source at power-up.

Program operation may further be terminated without the reprogram operation when the flag information indicates an on state of the reprogram operation.

An exemplary embodiment may further comprise a flash memory device comprising an array of memory cells arranged in rows and columns, a row decoder circuit configured to select one of the rows, a register block configured to store data to be programmed in the memory cells of the selected row, a backup parameter storage component configured to store flag information indicating an on/off state of a reprogram operation and address information and, a control block configured to control the register block and the row decoder block at a program operation.

When the program operation is determined as an unsuccessful program operation, the control block may be configured to determine a reprogram operation according to the flag information in the backup parameter storage component. When the flag information indicates an on state of the reprogram operation, the control block may controls the register block and the row decoder circuit so that data stored in the register block is reprogrammed in the array without external control.

Address information and the flag information may be loaded onto the backup parameter storage component from the array at power-up.

Address information and the flag information may be loaded onto the backup parameter storage component from the external source before a normal operation.

Address information and the flag information may be loaded onto the backup parameter storage component from the external source at power-up.

When the flag information indicates an on state of the reprogram operation, the control block may set the row decoder circuit with the address information in the backup parameter storage component so as to select memory cells of a different row from the selected row.

The register block may include page buffers each corresponding to the columns.

Each of the page buffers may include first and second registers controlled by the control block, the first register may be configured to retain the data to be programmed as original data and the second register may be configured to drive a corresponding bit line according to the data to be programmed.

The control block may control the register block so that the original data of the first register may be reprogrammed in the array at the reprogram operation.

When the flag Information indicates an on state of the reprogram operation, the control block may terminate the program operation without the reprogram operation,

An exemplary embodiment may further comprise a memory system comprising a memory controller and a flash memory device operating responsive to a control of the memory controller. The flash memory device may further comprises, an array of memory cells arranged In rows and columns, a row decoder circuit configured to select one of the rows, a register block configured to store data to be programmed in memory cells of the selected row, a backup parameter storage component configured to store flag information indicating an on/off state of a reprogram operation and address information and a control block configured to control the register block and the row decoder block at a program operation. When the program operation is determined to be an unsuccessful program operation, the control block may be configured to determine a reprogram operation according to the flag information in the backup parameter storage component and when the flag information indicates an on state of the reprogram operation, the control block may control the register block and the row decoder circuit so that data stored in the register block may be reprogrammed in the array without external control.

The register block may further include page buffers each corresponding to the columns.

Each of the page buffers may include first and second registers controlled by the control block the first register may be configured to retain the data to be programmed as original data and the second register may be configured to drive a corresponding bit line according to the data to be programmed.

The control block may further control the register block so that the original data of the first register may be reprogrammed in the array at the reprogram operation.

The address information and the flag information may be loaded onto the backup parameter storage component from the external source before a normal operation or at power-up.

When the flag information indicates an on state of the reprogram operation the control block may set the row decoder circuit with the address information in the backup parameter storage component so as to select memory cells of a different row from the selected row.

When the flag information indicates an on state of the reprogram operation, the control block may terminate the program operation without the reprogram operation.

The memory system may further include a memory card.

### BRIEF DESCRIPTION OF THE DRAWINGS

FIG. 1 is a block diagram showing a conventional memory system including a flash memory device.

FIG. 2 Is a diagram showing a program procedure of a flash memory device illustrated in FIG. 1.

FIG. 3 is a block diagram showing a flash memory device according to the present invention.

FIG. 4 is a block diagram showing a part of a register block illustrated in FIG. 3.

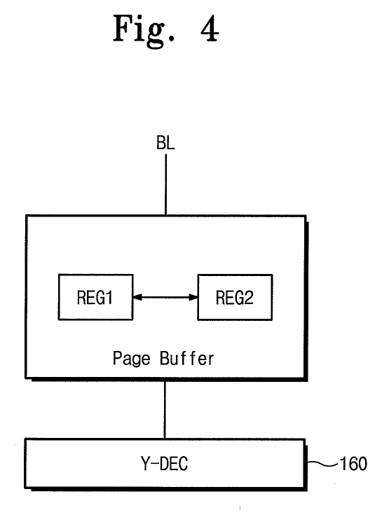

FIG. 5 is a flowchart for describing a program operation of a flash memory device according to an exemplary embodiment of the present invention.

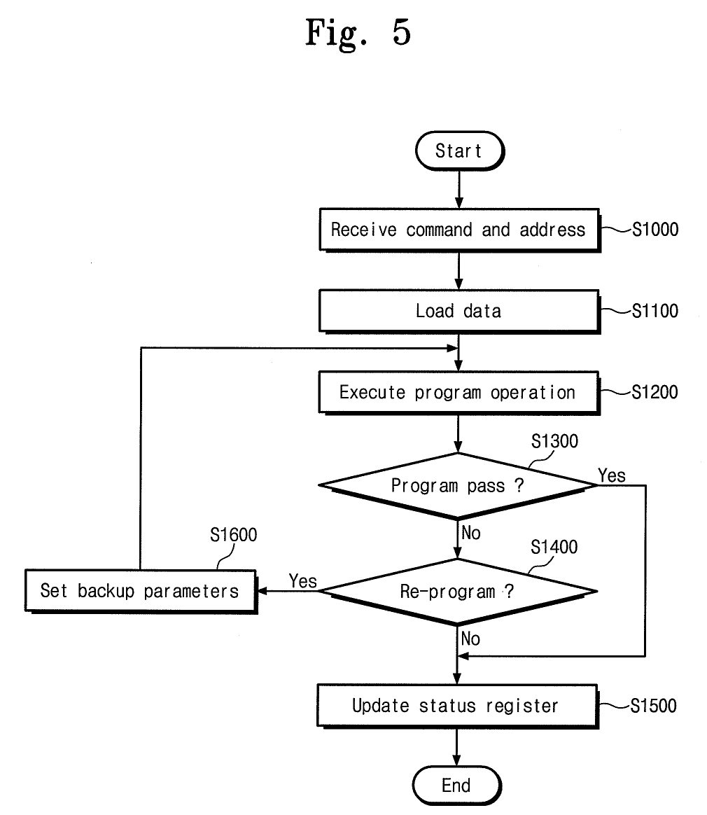

FIG. 6 is a diagram showing a program procedure of a flash memory device illustrated in FIG. 3.

FIG. 7 is a block diagram showing a system including a flash memory device according to the present invention.

### DETAILED DESCRIPTION OF EXEMPLARY EMBODIMENTS

The present invention will now be described more fully hereinafter with reference to the accompanying drawings, in which exemplary embodiments are shown. This invention, however, may be embodied in many different forms and should not be construed as limited to the embodiments set forth herein. In the drawings, like numbers refer to like elements throughout.

A flash memory device of the present exemplary embodiment may be realized to include an automatic data backup function where a data backup operation is automatically carried out without data reloading and external control when programming is unsuccessful. With the automatic data backup function of the present invention, it is possible to reprogram data without lowering of the effective operating speed of a memory system including a flash memory device.

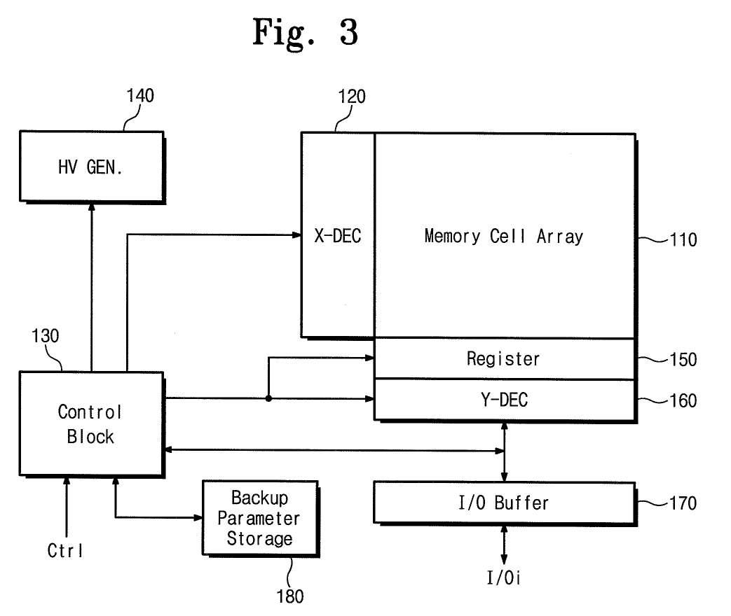

FIG. 3 is a block diagram showing a flash memory device according to an exemplary embodiment of the present invention. The flash memory device may be a NAND flash memory device or other memory device such as MROM, PROM, FRAM, NOR flash memory device, and the like.

Referring to FIG. 3, a flash memory device according to an exemplary embodiment of the present invention includes a memory cell array 110 for storing data information. The memory cell array 110 may include memory cells arranged in intersections of rows (or, word lines) and columns (or, bit lines). Each of the memory cells may store N-bit data (N is 1 or more integer). A row decoder circuit 120 may be controlled by a control block 130, and selects at least one of the rows of the memory cell array 110. The row decoder circuit may drive the selected row (or, word line) with a word line voltage that is generated by a high voltage generator circuit 140. A register block 150 may operate in response to the control of the control block 130. The register block 150 may be configured to store data to be programmed at the memory cell array 110 at a program operation and to read data from the memory cell array 110 at a read operation.

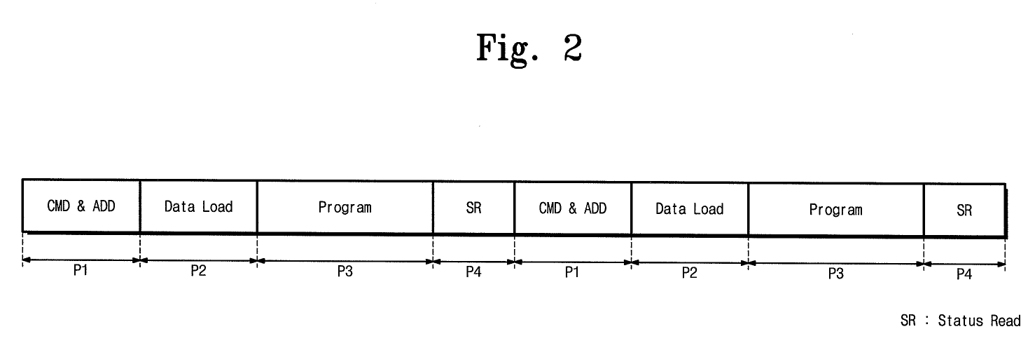

The register block 150 may comprise of a plurality of page buffers, each of which may be configured to be connected to one column (or bit line) or either one of two columns (or bit lines). Each of the page buffers may operate a write driver or a sense amplifier according to a mode of operation. For example, each of the page buffers may operate as a write driver at a program operation and as a sense amplifier at a read operation. Each of the page buffers may include at least two registers REG1 and REG2 as illustrated in FIG. 2. One of the registers REG1 and REG2 may be used to retain loaded data until a program operation is ended, and the other may be used to program a memory cell according to the loaded data (or, to drive a corresponding bit line according to the loaded data). For example, assume that data received during a data load interval is stored in the register REG2. According to this assumption, data loaded onto the register REG2 may be sent to the register REG1 according to the control of the control block before a program operation is carried out. A memory cell may be programmed in a conventional manner (e.g., F-N tunneling manner) according to the transferred data to the register REG1. While a program operation is carried out using the register REG1, stored data in the register REG2 may be maintained without change under the control of the control block 130. Alternatively, data from the external source may be simultaneously provided to the registers REG1 and REG2 during a data load interval. In this case, while a program operation is carried out using the register REG1, data stored in the register REG2 may be retained without change under the control of the control block 130. Data stored in the register REG2 may be used at a data backup operation to be performed according a program result.

Returning to FIG. 3, a column decoder circuit 160 is controlled by the control block 130, and selects columns of the memory cell array 110 or page buffers of the register block 150 by a given unit in response to a column address. An input/output buffer block 170 may transfer data input via input/output pins I/Oi to the register block 150 via the column decoder circuit 160 during a data load interval of a program operation. The input/output buffer block 170 may output to the external data sent from the register block 150 via the column decoder circuit 160 during a data output interval of a read operation. In particular, during a read operation such as a verify read operation, data in the register block 150 may be sent to the control block 130 via the column decoder circuit 160. The control block 130 may verify whether received data is successfully programmed data or unsuccessfully programmed data. If the received data is successfully programmed data, the control block 130 may perform a verify operation with respect to next data. This verify operation may be repeated until memory cells of a selected row/page are all selected. If the successfully programmed data is received until memory cells of a selected row/page are all selected, the control block 130 may store a status value indicating program pass in a standard industry status register. On the other hand, if received data is unsuccessful program data, the control block 130 may terminate a program operation and store a status value indicating unsuccessful programming in a status register. A status value in a status register may be provided to the external source via a status read operation that is well known in the art.

In particular, when a program operation is determined to be unsuccessful, the control block 130 may determine a reprogram operation according to backup parameter information stored in a backup parameter storage component 180. The backup parameter information in the backup parameter storage component 180 may include flag information indicating a reprogram operation, block address information, row/page address information, and the like. When the flag information indicates an on state of the reprogram operation, the reprogram operation may be carried out without external control and without reloading of program data under the control of the control block 130. When the flag information indicates an off state of the reprogram operation, the control block 130 may terminate a program operation and store a status value in the same manner as described above. The block address information is an address for designating a free memory block, and the row/page address information is an address for designating a page where data of an unsuccessfully programmed page is stored. When a reprogram operation is carried out, the block and page address information may be transferred to the row decoder circuit 120 under the control of the control block 130.

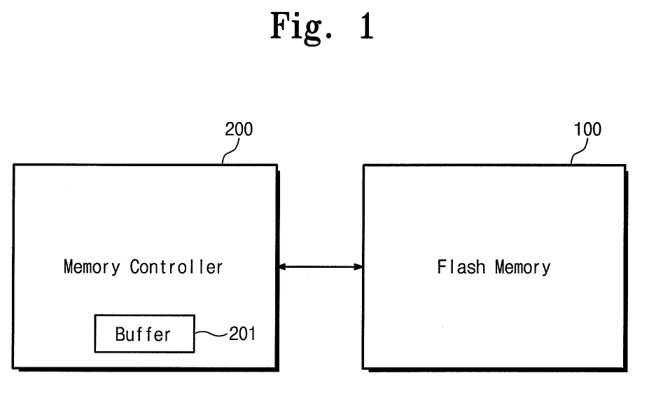

In accordance with a flash memory device of the present invention, backup parameter information may be stored in the backup parameter storage component 180 in various ways. For example, the backup parameter information may be stored in any region of the memory cell array 110. The backup parameter information thus stored may be sent to the backup parameter storage component 180 under the control of the control block 130 at power-up. Alternatively: the backup parameter information may be stored in the backup parameter storage component 180 under the control of a memory controller (200 in FIG. 1) before a normal operation is carried out. Alternatively, the backup parameter information may be stored in the backup parameter storage component 180 at request of a user.

In this embodiment, a flash memory device and a memory controller may include a memory system. For example, the memory system may include a memory card. The present exemplary embodiment is not limited to a memory system which includes a memory card.

As illustrated in the above description, a flash memory device according to an embodiment of the present invention performs a reprogram operation with respect to a failed page without external control and reloading of program data when a program operation is determined to have failed. Accordingly a flash memory device operates reliably without lowering of operation performance of a memory system including a flash memory device.

FIG, 5 is a flowchart for describing a program operation of a flash memory device according to an embodiment of the present invention. When a program operation is required from the external source (e.g. a host), data to be programmed may be stored in a buffer memory (201 in FIG. 1) of a memory controller (200 in FIG. 1). Once data to be programmed is stored in the buffer memory 201: the memory controller 200 may transfer command, address and data to a flash memory device according to a given timing. Afterwards, the memory controller 200 does not begin an operation of the flash memory device until there is received flag information (e.g., R/nB signal) indicating completion of a program operation from the flash memory device.

In step S1000, a command and an address may be sent to the flash memory device from the memory controller 200 according to a given timing. The command may be sent to a control block 130 via an input/output buffer block 170, and the address is sent to row and column decoder circuits 120 and 160 via the input/output buffer block 170. In the next step S1100, data stored in the buffer memory 201 may be stored in a register block 150 through the input/output buffer block 170 and a column decoder circuit 160. As described above, loaded data may be retained in a register REG2 of each page buffer. At a program operation, data stored in the register REG2 may be transferred to a register REG1 under the control of the control block 130. Once data to be programmed is all sent to the register block 150, the control block 130 may output flag information of a busy state to the memory controller 200.

Afterwards, in step S1200, data loaded in the register block 150 may be programmed in memory cells of a selected page under the control of the control block 130. As above described: a program operation includes a program execution interval and a verify interval that constitute a program loop. Memory cells of a selected page are programmed during the program execution interval and during the verify interval, there is verified whether the memory cells of the selected page are successfully programmed. During the verify interval, data may be read from memory cells of the selected page via the registers REG1 in the register block 150. At this time, data stored in the registers REG2 of the register block 150 may be retained without change. The read data may be sent to the control block 130 via the column decoder circuit 160, and the control block 130 may verify whether the input data is program pass data. If the input data is determined to be successfully programmed data until page buffers in the register block 150 are all selected, the control block 130 may store a status value of program successful in a status register and terminate a program operation (S1400).

Alternatively, if the input data is determined to be unsuccessfully programmed, the control block 130 may repeat a program operation within a given program loop number. If the program operation is determined to be an unsuccessful program operation after the given program loop number, the control block 130 may check whether a reprogram operation is carried out based on backup parameter information in a backup parameter storage component 180 (S3400). If flag information of the backup parameter information indicates an off state of a reprogram operation, in step S1500, the control block 130 may store a status value of unsuccessful program operation in the status register and terminate a program operation.

If the flag information indicates an on state of the reprogram operation, the control block 130 makes block and page address information in the backup parameter storage component 180 be set to the row decoder circuit 120. Afterwards, the procedure goes to the step S1200. After the row decoder circuit 120 is newly set with the block and page address information, a program operation may be again performed in the same manner as above described The reprogram operation may be carried out automatically using data stored in the registers REG2 without external control and reloading of program data. Data stored in the registers REG1 is different from original data when a program operation is terminated. For this reason, a reprogram operation may be performed using original data stored in the registers REG2. The reprogram operation is substantially identical with the above-described program operation. When the reprogram operation is completed, in step S1500, the control block 130 may update the state register with a status value of program pass and terminate the program operation.

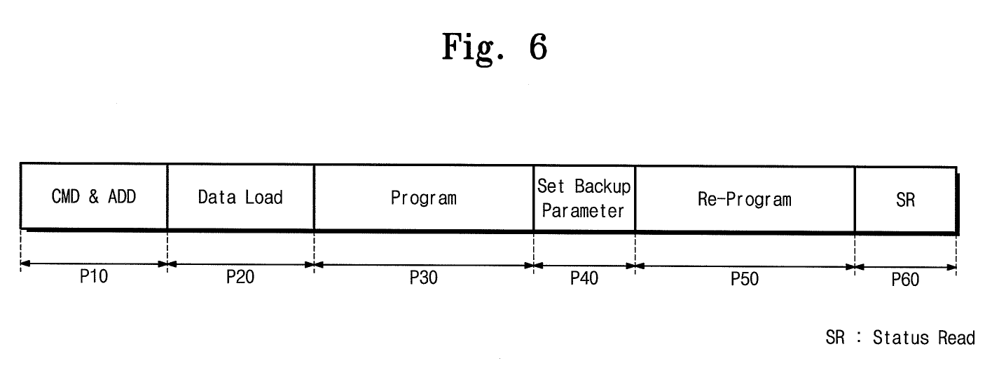

When a program operation is required, as illustrated in FIG. 6, a flash memory device according to an embodiment of the present invention is configured to receive a command and an address (P10), to receive data to be programmed (P20), to execute a program operation (P30), to set a row decoder circuit with address information for a reprogram operation when a program operation is failed (P40), to execute a reprogram operation (P50) and to perform a status read operation (P60). The intervals P40 and P50 may be skipped when flag information stored in the backup parameter storage component 180 indicates an off state of a reprogram operation.

When a program operation is determined to be unsuccessful, a flash memory device according to the present exemplary embodiment may perform a reprogram operation without external control and reloading of program data. This means that reliability of a flash memory device is improved without compromising the performance of a memory system including a flash memory device. Further, since a reload operation is not needed to perform a reprogram operation a memory controller needs no additional buffer memory to store data for a reprogram operation. This means that a reprogram operation is carried out without greater costs to the memory controller.

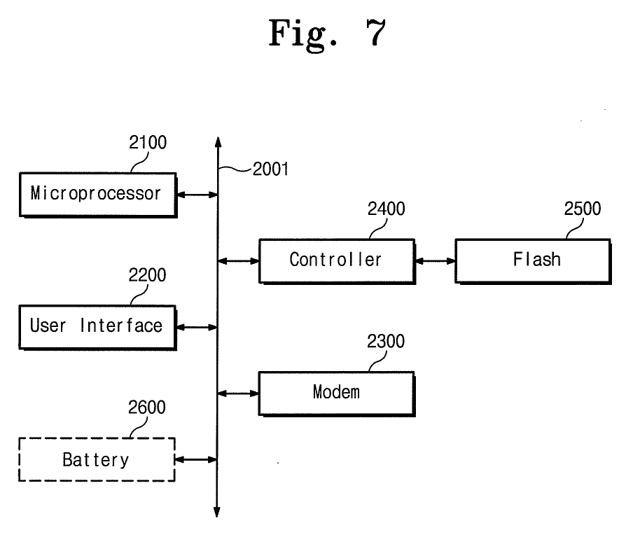

Flash memory devices are kinds of nonvolatile memories capable of keeping data stored therein even absent a power supply. With the increase in popularity of mobile devices such as cellular phones, personal digital assistants (PDA), digital cameras, portable gaming consoles, and MP3s, the flash memory devices are widely employed as code storage, as well as data storage. The flash memory devices may be also be used in home applications such as high-definition TVs, digital versatile disks (DVDs), routers, and global positioning systems (GPSs). FIG. 7 is a block diagram showing a schematic computing system including the flash memory device of an embodiment of the present invention. The computing system according to the present exemplary embodiment comprises a processing unit 2100 such as a microprocessor or a central processing unit, a use interface 2200, a modem 2300 such as a baseband chipset, a memory controller 2400, and the flash memory device 2500. The flash memory device 2500 may be configured as like that shown FIG. 3 in substance. N-bit data (N is a positive integer) to be processed by the processing unit 3000 are stored in the flash memory device 2500 through the memory controller 2000. If the computing system shown in FIG. 7 is a mobile device, it may further be comprised of a battery 2600 for supplying power thereto. The computing system may be further equipped with an application chipset, a camera image processor (e.g., CMOS image sensor, CIS), a mobile DRAM, etc.

Although the present invention has been described in connection with the embodiments of the present invention illustrated in the accompanying drawings, it is not limited thereto.

What is claimed is:

1. A method of programming a flash memory device which includes an array of memory cells arranged in rows and columns, comprising,
programming memory cells of a selected row with loaded data;
determining whether the memory cells of the selected row are successfully programmed;
when the result is determined as a unsuccessful program operation, determining a reprogram operation according to flag information indicating an on/off state of the reprogram operation stored in the flash memory device; and
when the flag information indicates an on state of the reprogram information reprogramming the loaded data to memory cells of a different row from the selected row.

2. The method of claim 1, wherein the memory cells of the different row are selected by address information stored in the flash memory device.

3. The method of claim 2, wherein the address information and the flag information are stored in a backup parameter storage component of the flash memory device.

4. The method of claim 3, wherein the address information and the flag information are loaded onto a backup parameter storage component from the array at power-up.

5. The method of claim 3, wherein the address information and the flag information are loaded onto a backup parameter storage component from the external source before a normal operation.

6. The method of claim 3, wherein the address information and the flag information are loaded onto a backup parameter storage component from the external source at power-up.

7. The method of claim 1, further comprising:
terminating the program operation without the reprogram operation when the flag information indicates an on state of the reprogram operation.

8. A flash memory device comprising:
an array of memory cells arranged in rows and columns;
a row decoder circuit configured to select one of the rows;
a register block configured to store data to be programmed in memory cells of the selected row;
a backup parameter storage component configured to store flag information indicating an on/off state of a reprogram operation and address information; and
a control block configured to control the register block and the row decoder block at a program operation,
wherein when the program operation is determined to be unsuccessful, the control block is configured to determine a reprogram operation according to the flag information in the backup parameter storage component; and when the flag information indicates an on state of the reprogram operation, the control block controls the register block and the row decoder circuit so that data stored in the register block is reprogrammed in the array without external source control.

9. The flash memory device of claim 8, wherein the address information and the flag information are loaded onto the backup parameter storage component from the array at power-up.

10. The flash memory device of claim 8, wherein the address information and the flag information are loaded onto the backup parameter storage component from the external source before a normal operation.

11. The flash memory device of claim 8, wherein the address information and the flag information are loaded onto the backup parameter storage component from the external source at power-up.

12. The flash memory device of claim 8, wherein when the flag information indicates an on state of the reprogram operation, the control block sets the row decoder circuit with the address information in the backup parameter storage component so as to select memory cells of a different row from the selected row.

13. The flash memory device of claim 8, wherein the register block includes page buffers each corresponding to the columns.

14. The flash memory device of claim 13, wherein each of the page buffers includes first and second registers controlled by the control block, the first register configured to retain the data to be programmed as original data and the second register configured to drive a corresponding bit line according to the data to be programmed.

15. The flash memory device of claim 14, wherein the control block controls the register block so that the original data of the first register is reprogrammed in the array at the reprogram operation.

16. The flash memory device of claim 8, wherein when the flag information indicates an on state of the reprogram operation, the control block terminates the program operation without the reprogram operation.

17. A memory system comprising:
a memory controller; and
a flash memory device operating responsive to a control of the memory controller, wherein the flash memory device comprises:
an array of memory cells arranged in rows and columns;
a row decoder circuit configured to select one of the rows;
a register block configured to store data to be programmed in memory cells of the selected row;
a backup parameter storage component configured to store flag information indicating an on/off state of a reprogram operation and address information; and
a control block configured to control the register block and the row decoder block at a program operation,
wherein when the program operation is determined to be as a unsuccessful program operation the control block is configured to determine a reprogram operation according to the flag information in the backup parameter storage component; and when the flag information indicates an on state of the reprogram operation, the control block controls the register block and the row decoder circuit so that data stored in the register block is reprogrammed in the array without external control.

18. The memory system of claim 17, wherein the register block includes page buffers each corresponding to the columns.

19. The memory system of claim 18, wherein each of the page buffers includes first and second registers controlled by the control block, the first register configured to retain the data to be programmed as original data and the second register configured to drive a corresponding bit line according to the data to be programmed.

20. The memory system of claim 19, wherein the control block controls the register block so that the original data of the first register is reprogrammed in the array at the reprogram operation.

21. The memory system of claim 19, wherein the address information and the flag information are loaded onto the parameter storage component from the external source before a normal operation or at power-up.

22. The memory system of claim 17, wherein when the flag information indicates an on state of the reprogram operation, the control block sets the row decoder circuit with the address information in the backup parameter storage component so as to select memory cells of a different row from the selected row.

23. The memory system of claim 17, wherein when the flag information indicates an on state of the reprogram operation, the control block terminates the program operation without the reprogram operation.

24. The memory system of claim 17, wherein the memory system includes a memory card.
